(19) United States
(12) Patent Application Publication
(10) Pub. No.: US 2014/0326298 A1
(43) Pub. Date: Nov. 6, 2014

(54) HEAT REJECTING OPTIC

(71) Applicant: AMONIX, INC., Seal Beach, CA (US)

(72) Inventors: Aditya Nayak, Seal Beach, CA (US); Geoffrey S. Kinsey, Pasadena, CA (US)

(73) Assignee: AMONIX, INC., Seal Beach, CA (US)

(21) Appl. No.: 14/095,888

(22) Filed: Dec. 3, 2013

Related U.S. Application Data
(63) Continuation of application No. 13/187,372, filed on Jul. 20, 2011, now abandoned.

(51) Int. Cl. H01L 31/052; G02B 27/10; H01L 31/18; H01L 31/0232

(52) U.S. Cl. CPC H01L 31/0524; H01L 31/02325; G02B 27/1006; H01L 31/18
USPC 136/255; 136/259; 359/639; 438/69

(57) ABSTRACT

A heat-rejecting optic comprising an optical element and receiving element or layer with intermediate layer between is provided. Refractive indices of the optical element and receiving element or layer are greater than the intermediate layer. The optic may be part of a concentrator assembly or lens concentrator system for photovoltaic cells. The heat-rejecting optic functions to redirect wavelengths of light for which power conversion by a photovoltaic cell is inefficient and which cause undesirable photovoltaic cell heating and damage, reducing photovoltaic cell life. The receiving element or layer and intermediate layer modify the optical element to frustrate the total internal reflection of light that would otherwise occur within the optical element and divert that light into the receiving element or layer.

### CROSS-REFERENCE

This application is a continuation application of Ser. No. 13/187,372, filed Jul. 20, 2011, which is incorporated herein by reference in its entirety.

### BACKGROUND

1. Field of the Invention

The present invention relates to concentrators for photovoltaic cells that reduce thermal damage to photovoltaic cells by deflecting some wavelengths of radiation for which the efficiency of power production is outweighed by heating damage to the photovoltaic cell. The present invention also relates to methods of reducing thermal damage to solar arrays and methods of manufacturing solar power modular assemblies to enhance power conversion efficiency and improve durability.

2. Description of the Related Art

Preventing thermal damage to photovoltaic cells is especially a concern with concentrated photovoltaic (CPV) and highly concentrated photovoltaic (HCPV) multijunction photovoltaic cells. Heat rejection is critical for operation and durability of a CPV or HCPV system. Power production decreases by more than 1% for every 10° C. temperature increase. More importantly, durability is severely compromised by unwanted heating as every 10° C. rise in operating temperature cuts photovoltaic cell lifetime in half.

The traditional means for reducing thermal damage in photovoltaic cells is with heat sinks. However, in CPV and HCPV systems providing concentrations greater than 1000× heat sinks can be prohibitively expensive and insufficient to prevent thermal damage to the extent needed for optimal performance and cost competitiveness of solar power systems.

One alternative for rejecting heat that would otherwise be transferred to a photovoltaic cell and optionally, the photovoltaic cell's associated heat sink, is use of band stop filters. Band stop filters may be placed in the light path between the photovoltaic cell and light source to filter out unwanted infrared (IR) radiation (light having wavelengths beyond about 1800 nm). Unfortunately, these filters are expensive and degrade with time such that the theoretically intuitive solution is less than desirable as applied in practice.

Accordingly, new assemblies and methods are needed for rejecting heat transferred from a nonselective source of radiation (for example, the sun) to a photovoltaic cell, especially for arrays of CPV and HCPV multijunction photovoltaic cells, and III-V multijunction photovoltaic cells in particular. These new assemblies and methods can be used as an alternative or substitute, compliment, or supplement to traditional heat sinks and/or band stop filters, as necessary to provide optimal power efficiency, durability, and cost effectiveness. For example, by using alternative FTIR concentrator assemblies and methods, as described further herein, together with heat sinks, the thermal loading on the sinks can be reduced so that the amount of expensive materials, such as, for example aluminum, copper, and the like used in traditional heat sinks to absorb the thermal loading, can be reduced. The present invention satisfies this and other needs.

### SUMMARY OF THE INVENTION

In its most general aspect, the present invention provides multifunctional assemblies of optical elements above and/or around a photovoltaic cell or solar array that act to both focus or concentrate desired wavelengths of light onto the photovoltaic cell while rejecting unwanted wavelengths of light that would cause too much thermal damage relative to the amount of power they would generate given a photovoltaic cell's wavelength dependent conversion efficiency. In this manner, the multifunctional assemblies of optical elements operate to improve solar power production efficiency while preserving the photovoltaic cell.

In other aspects, the multifunctional assemblies of optical elements may include light concentrator(s), lens(es), prism(s), light pipe(s), intermediate material(s), intermediate layer(s), receiving element or layer(s) and other element(s). Using a particular arrangement of optical elements above and around the photovoltaic cell, unwanted energy (for example, infrared radiation beyond 1800 nm, especially 1800-2000 nm) can be redirected from a trajectory toward the photovoltaic cell to an alternative trajectory away from and outside of the photovoltaic cell.

In still other aspects, the invention provides an improved design for optical elements that utilize the principal of Total Internal Reflection (TIR) to concentrate light on a photovoltaic cell. Utilizing refractive optical elements which may include one or more of a primary optical element, for example, a Fresnel lens, and a secondary optical element, for example, a prism or light pipe, together with a receiving element or layer having a refractive index higher than the refractive index of an intermediate layer between the optical element(s) and the receiving element or layer results in Frustrated Total Internal Reflection (FTIR) of light inside the optical element. Accordingly, unwanted light inside the optical element that would otherwise be internally reflected and directed onto a photovoltaic cell is induced by the lower refractive index intermediate layer in between and adjacent higher refractive index receiving element or layer to leave the interior of the optical element, pass through the intermediate layer, and enter the receiving element or layer. In the receiving element or layer, the unwanted wavelengths of energy cause less damage than they would if they entered the photovoltaic cell. In additional aspects, the unwanted wavelengths passed to the receiving element or layer may provide no undesirable effects on the receiving element or layer and may even be utilized to provide desirable effects such as, for example, thermal heating of air, water, and the like.

Other features and advantages of the present invention will become apparent from the following detailed description, taken in conjunction with the accompanying drawings, which illustrate, by way of example, the principles of the invention.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic diagram of a prior art optical system with a TIR glass prism as the secondary optical element (SOE) and a Fresnel lens as the primary optical element (POE).

FIG. 2 is a cross-sectional view illustrating the operation of one embodiment of the present invention.

FIG. 3 is a cross-sectional view illustrating the operation of the embodiment of FIG. 2 of the present invention as used in a concentrator assembly.

FIG. 4 shows a cross-sectional view illustrating the operation of the embodiment of FIG. 2 of the present invention as used with a multi-junction photovoltaic cell.

### DETAILED DESCRIPTION OF THE PREFERRED EMBODIMENTS

Definitions

As used herein, the following terms are defined as indicated below, consistent with the principle that a patentee can be his own lexicographer.

“Intermediate layer” refers to a thin (sub-wavelength) layer having a lower refractive index positioned between an optical element and receiving element or layer having higher refractive indices than it. The intermediate layer may be, but is not limited to, an air gap or magnesium fluoride (MgF₂). In cases in which the intermediate layer is a material composition it may be coated on the receiving element or layer or optical element, including through dipping, spray deposition, or other methods.

“Receiving element or layer” refers to a medium having a higher refractive index than the intermediate layer and separated from an optical element by the intermediate layer into which the evanescent wave of undesired wavelengths coupled out of the optical element is received. The receiving element or layer may take any one of a variety of different forms including, for example: (i) a block of material, for example, a glass prism, placed near and on the side of the optical element and intermediate layer, (ii) a block of material in the form of a substrate, and (iii) a coating on the optical element and/or intermediate layer.

“Evanescent wave” refers to a standing wave present at a boundary where TIR occurs or would occur absent elements responsible for FTIR. The boundary condition satisfies Maxwell's equations and no net energy is lost. The energy of the incoming wave is equal to the energy of the totally internally reflected wave.

“Total Internal Reflection (TIR)” refers to the process in which all of the energy that enters an object, for example, the optical element, is internally reflected by the inner surfaces of the object. The incoming energy to the object equals the energy of the totally internally reflected wave. In practice, TIR is not perfect and some energy is lost through absorption and scattering (diffusion). TIR results when a beam of light is reflected from the surface of an optically “less dense” material. For example, a beam from an underwater light source can be reflected from the surface of the water, rather than escaping through the surface. TIR only occurs if a light beam hits a surface at an angle greater than the critical angle for that particular pair of materials. In this case, TIR only occurs if a light beam inside the optical element hits a boundary formed by the optical element with the intermediate layer at an angle greater than the critical angle for that combination. More specifically, this critical angle may be based on a glass optical element together with air as the intermediate layer, or with magnesium fluoride (MgF₂) as the intermediate layer. TIR is used as a means of reflecting light inside optical elements, such as, for example prisms, light pipes, and optical fibers. Light is contained inside an optical element not by the cladding or sleeve around it, but by the ability of the internal surface of the optical element to reflect 100% of the light, thereby keeping it trapped inside the optical element.

“Frustrated Total Internal Reflection (FTIR)” refers to the phenomenon that occurs when an evanescent wave (such as that produced by TIR) extends across a separating medium, such as a lower refractive index air gap or intermediate material layer into a region occupied by a higher index of refraction material, such as the receiving element or layer described herein, causing some energy to flow across the TIR boundary. This phenomenon, known as FTIR, is similar to quantum mechanical tunneling or barrier penetration. When transmission across the boundary occurs in this manner, the “total internal reflection” (within the optical element) is no longer total since the transmitted FTIR wave comes at the expense of the internally reflected one. Frustrated total internal reflection is also sometimes referred to as partial internal reflection.

“Optical element (OE)” refers to an element that light encounters on a trajectory from a light source (for example, the sun) to a photovoltaic cell. The OE generally functions to attenuate, focus, concentrate, amplify, absorb, scatter, diffuse, diffract, reflect, refract or redirect light. As used herein, both the primary optical element (POE) and secondary optical element (SOE) are examples of optical elements.

“Primary optical element (POE)” refers to an optical element or lens that light contacts first, along its trajectory or pathway from a light source to a photovoltaic cell. For example, the primary optical element may be a Fresnel lens. The primary optical element may operate to attenuate, focus, concentrate, amplify, absorb, scatter, diffuse, diffract, reflect, refract or redirect light before the light reaches the secondary optical element or another destination along the light trajectory from a light source to a photovoltaic cell or other destination. POEs may be reflective, refractive, or a hybrid. Common materials for POEs include but are not limited to poly (methyl methacrylate) and silicone on glass (SOG).

“Fresnel lens” refers to a special type of lens having a relatively short focal length and large diameter that reduces the amount of material required to concentrate light by splitting the lens into a set of concentric annular sections known as Fresnel zones. The use of these zones allows keeping the required curvature without increasing the thickness of the lens, by means of adding discontinuities between each Fresnel tone.

“Secondary optical element (SOE)” refers to an optical element or lens that light contacts after it passes through the first optical element on its trajectory to the photovoltaic cell or other destination. Commonly, the secondary optical element is a prism or light pipe utilizing total internal reflection (TIR) to guide light to a photovoltaic cell. The SOE may provide one or more of the following functional advantages: further concentration of light before reaching the photovoltaic cell, increasing the acceptance angle (for example, for Fresnel- and prismatic-lenses concerning different photosensitive areas of photovoltaic cells), shaping the light beam cross-section, and improving flux uniformity. SOEs can be reflective or refractive. Several embodiments of the present invention are primarily directed at a concentrator assembly that modifies or works in association with the refractive type of SOEs. However, in one or more embodiments the present invention may be adapted for use with reflective type SOEs. Shapes for reflective SOEs include (but are not limited to): truncated cone, truncated pyramid, compound parabolic concentrator (CPC), and crossed CPC. Shapes for refractive SOEs include, but are not limited to: kaleidoscope, domed kaleidoscope, half-egg (aspheric), Dielectric Totally Internally Reflecting Concentrator (DTIRC), and Fresnel Köhler SOE.

As discussed herein, according to several embodiments of the present invention the SOE is modified such that the modified SOE rejects longer wavelengths of light that contribute to photovoltaic cell heating and are not used for power generation or are used inefficiently for power generation. If the cost/benefit ratio of heating/power is above a specified threshold the wavelengths of light may be rejected. In one embodiment, wavelengths over 1800 nm are rejected, as these wavelengths would otherwise cause undesirable heating of the photovoltaic cell. In another embodiment, selected wavelengths below 1800 nm may also be rejected, as these wavelengths may be inefficiently converted to power by the photovoltaic cell.

The photovoltaic cell affiliated with the SOE to which preferred wavelengths of light are directed may be an individual photovoltaic cell specifically associated with each individual SOE or it may be a common slab waveguide at angles which guide by total internal reflection. In case of the common slab waveguide, coupled sunlight propagates within the slab until reaching a photovoltaic cell mounted along the edge(s) (See J. H. Karp, E. J. Tremblay and J. E. Ford, “Micro-Optic solar concentration and next-generation prototypes” IEEE Photovoltaics Specialists Conference Proceedings (2010) 978-1-4244-5892-9/10, which is expressly incorporated herein by reference in its entirety).

In its various embodiments, the present invention provides improved optics, concentrators, and assemblies of optics and concentrators with other auxiliary elements designed to redirect unwanted energy from a trajectory headed toward a photovoltaic cell, thereby reducing thermal damage to the photovoltaic cell and optionally, the photovoltaic cell's associated heat sink. The auxiliary element may be an intermediate layer comprising an air gap or a composition of one or more materials (or material layers) having a lower refractive index than the optical element and the receiving element or layer at either side. The auxiliary element may also be a receiving element or layer near the photovoltaic cell and optical element and adjacent the intermediate layer. The receiving element or layer auxiliary element attracts the disfavored wavelength ranges to it for alternative uses or absorption without damage that impacts the operation of the photovoltaic cell.

Unwanted energy may comprise wavelengths of radiation for which the cost/benefit ratio does not justify directing the radiation to the photovoltaic cell. This may be due to the fact that the benefit of the radiation in terms of providing a source of energy for the photovoltaic cell to convert to power is low relative to the cost of the radiation in terms of the amount of heat damage caused to the photovoltaic cell and heat sink by absorption of such radiation which degrades the components and reduces photovoltaic cell life. The benefit of the radiation as a power source may be low for some wavelengths that are outside the photovoltaic cell's preferred range. Through the use of dopants, selection of materials, arrangement and thickness of layers, and adjustment of other variables, photovoltaic cells may be tuned to convert energy within specified wavelength ranges. When the radiation source (for example, the sun) is not selective in the wavelength ranges it emits to correspond with the most efficient conversion wavelengths of the photovoltaic cell, ideally other means are preferably employed to concentrate desirable wavelength ranges on the photovoltaic cell and redirect non-preferred wavelength ranges outside of the photovoltaic cell. When redirection is not possible or imperfect, other means such as heat sinks, are sometimes employed to deal with incoming radiation of non-preferred wavelengths and to control damage to the photovoltaic cell.

In CPV and HCPV systems infrared radiation having wavelengths greater than 1800 nm is especially problematic. In practice, reducing or eliminating radiation having wavelengths 1800 2000 nm from reaching the photovoltaic cell is particularly desirable. Preliminary modeling suggests that around 20% of the IR light in this 1800 2000 nm range can be coupled out through the FTIR system described herein without affecting the top, middle, and bottom sub-photovoltaic cells in III-V multijunction photovoltaic cells. In addition, radiation wavelengths below 1800 nm may also be candidates for rejection through the concentrator assembly if the photovoltaic cell cannot convert them to energy efficiently.

Even if such wavelengths do not have undesirable effects on the photovoltaic cell they may find a higher value use through redirection by the concentrator assembly. For example, deflecting certain wavelengths that are otherwise on a trajectory toward the photovoltaic cell through a TIR optical element with an adjacent lower refractive index intermediate layer and higher index receiving element or layer via FTIR may permit materials in the intermediate layer region or receiving element or layer to perform higher value uses of such energy such as, for example, water/air heating, vibration dampening, and the like. The arrangement of the lower refractive index intermediate layer and higher index receiving element or layer adjacent a side of the higher refractive index optical element effectively pulls a standing evanescent wave formed along a side inner surface of the optical element out of the optical element and into the intermediate layer and receiving element or layer.

Various embodiments of the present invention perform such redirection of energy by incorporating optical elements having higher refractive indices that direct light onto a photovoltaic cell through Total Internal Reflection (TIR). The two loss mechanisms for TIR are scattering and absorption. For perfect TIR the energy of the incoming wave is equal to the energy of the total internally reflected wave. At the point where TIR occurs, a boundary condition exists that satisfies Maxwell's equations in that no net energy is lost. However, a standing wave is formed at the boundary of the SOE and the intermediate layer. This standing wave is also referred to as an evanescent wave. If a medium of higher refractive index, for example, the receiving element or layer, is introduced sufficiently close to this boundary and the standing evanescent wave, the wave can be coupled out of the optical element and into the medium of higher refractive index, for example, into the receiving element or layer. The refractive index of the receiving element or layer to which the evanescent wave is transferred need not have a higher refractive index than the optical element in which internal reflection occurs and from which the wave is coupled out. For example, the optical element and the receiving element or layer may have the same refractive indices. By “higher refractive index” it is meant that the optical element and the receiving element or layer each have a higher refractive index than the intermediate layer disposed between them. The intermediate layer may be, for example, an air gap, a deposited layer of MgF₂ or other material having a suitable refractive index.

The distance between an edge or side of the optical element facing an edge or side of the receiving element or layer influences the wavelength selectivity of the standing evanescent wave that is induced out of the optical element. This distance is filled by the intermediate layer having a lower refractive index than the indices of both the optical element and the receiving element or layer. The thickness of the intermediate layer, which in turn determines the distance between the optical element and the receiving element or layer influences wavelength selectivity of the composite optical device. The material composition of the intermediate layer also influences wavelength selectivity of the composite device as the refractive index of the intermediate layer depends on material composition.

The distance between the optical element and the receiving element or layer must be on the order of one wavelength of the wave to be ejected out of the optical element, so as to induce the standing evanescent wave at the boundary of the optical element to be coupled out into the intermediate layer and receiving element or layer rather than being internally reflected, absorbed, or scattered. In practice use of a material such as MgF₂ may be preferable to an air gap because such a layer is easier to reproducibly fabricate. Since the thickness of the material layer has to be sub-wavelength to fit between the optical element and the receiving element or layer, it may be difficult to fabricate a sandwiched air gap or to stably hold the optical element and the receiving element or layer a specified distance from each other without touching.

The receiving element or layer that receives the ejected wavelength of light from the optical element by FTIR may transfer the ejected light to other elements or components of the concentrator assembly or solar module. Alternatively, the receiving element or layer may absorb the ejected wavelengths of light. If the receiving element or layer absorbs the ejected wavelengths, it may degrade with time, resulting in damage to the receiving element or layer or reducing its capacity to continually absorb the ejected light. In these cases, the receiving element or layer may be replaceable so that when the ability of the receiving element or layer to absorb ejected light drops below a chosen performance standard, it may be replaced. Glass and silicone, and other materials known in the art, are preferred for the receiving element or layer. Replacing an exhausted receiving element or layer is less expensive than replacing a damaged photovoltaic cell or heat sink.

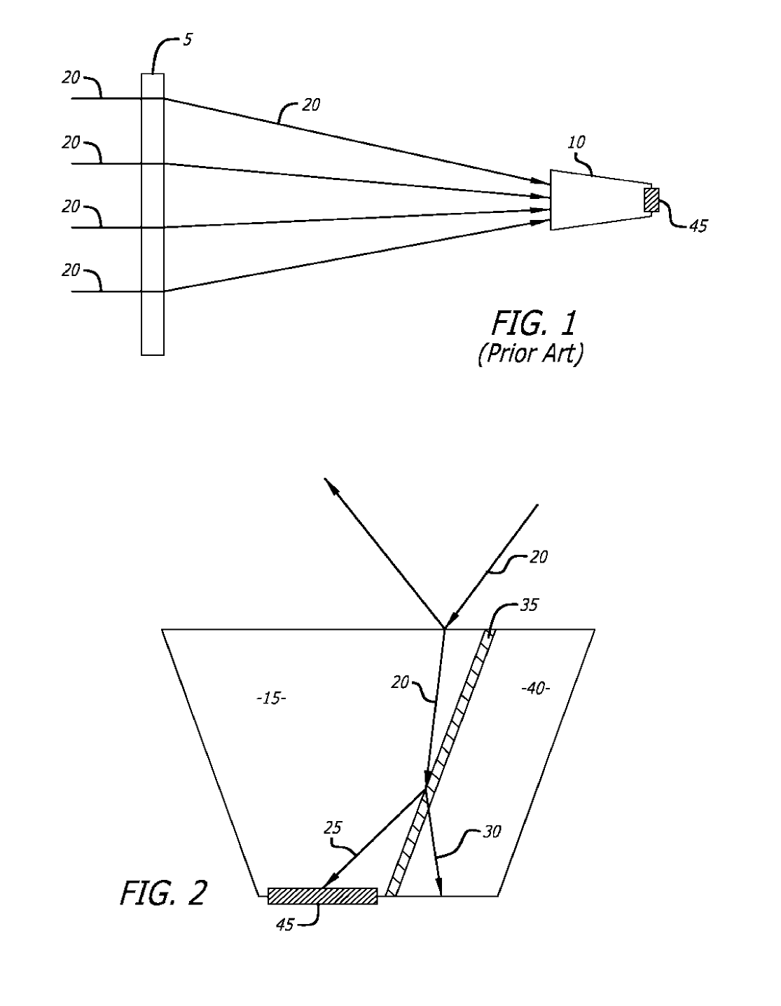

As shown in the prior art concentrator assembly of FIG. 1, substantially all of the incoming light 20 that passes through a primary optic 5 to reach the SOE 10 is internally reflected within the SOE, then passed along to the photovoltaic cell 45.

FIG. 2 depicts one embodiment of the present invention illustrating the modification of a SOE 15 to extract unwanted wavelengths 30 from the incoming light 20 through the intermediate layer 35 and into the receiving element or layer 40. As a result, the incoming light 20 is split into desired wavelengths 25 that the photovoltaic cell 45 can convert to energy efficiently and unwanted wavelengths 30 that are transferred out to the adjacent receiving element or layer 40 through the intermediate layer 35. In this embodiment, SOE 15 and receiving element or layer 40 have a higher refractive index than the intermediate layer 35 to induce specified wavelengths 30 of the incoming light 20 from a standing wave formed at a boundary of the SOE 15 and the intermediate layer 35 to enter the receiving element or layer 40.

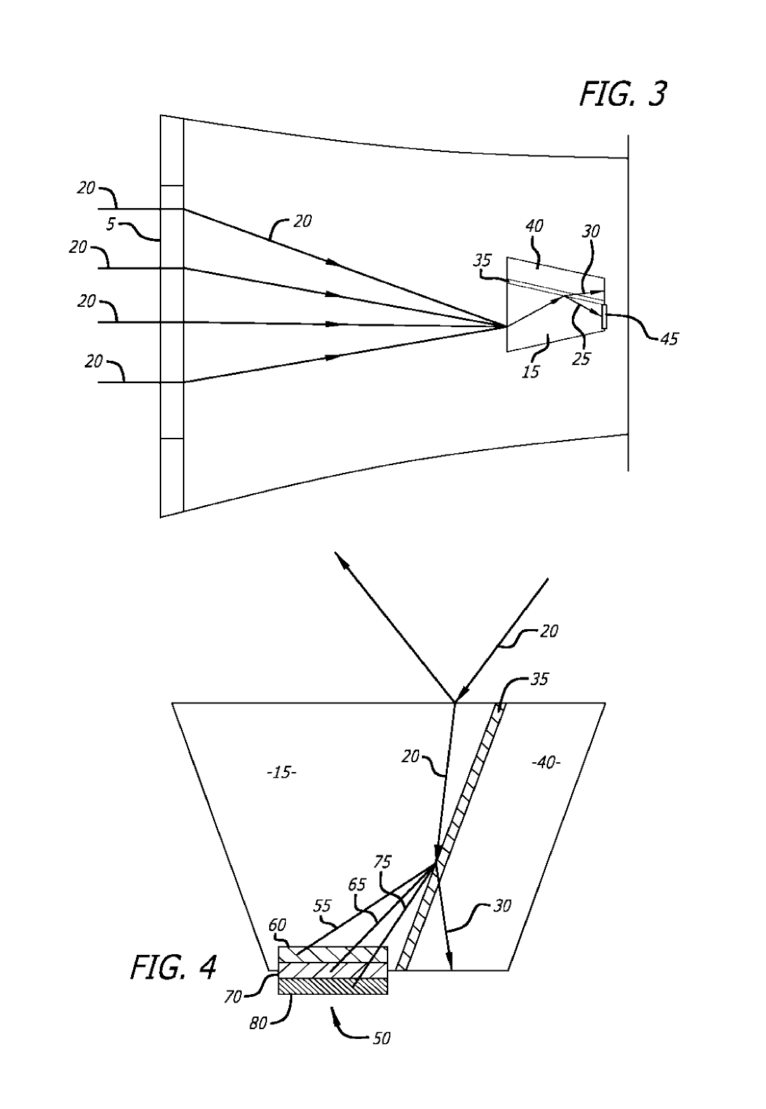

FIG. 3 shows a modified SOE 15, according to one embodiment of the present invention, as part of a concentrator assembly also including a primary optical element 5. As compared to FIG. 1 in which substantially all of the incoming light is totally internally reflected and passed to the photovoltaic cell, unwanted wavelengths 30 of incoming light 20 are rejected from the SOE 15 and pass instead to the receiving element or layer 40 without reaching the photovoltaic cell 45. Only desired wavelengths of light 25 that the photovoltaic cell 45 is capable of efficiently transforming into energy and that do not unnecessarily damage the photovoltaic cell are transferred to the photovoltaic cell.

As shown in FIG. 4, in embodiments of the present invention comprising multifunction photovoltaic cells 50, the incoming light may comprise blue wavelengths 55 for the top photovoltaic sub-cell 60, green wavelengths 65 for the middle photovoltaic sub-cell 70, and near infrared wavelengths 75 (greater than 1800 nm) for part of the bottom photovoltaic sub-cell 80. The TIR portion of the standing wave directed onward to the multijunction photovoltaic cell comprises the blue wavelengths 55 for the top photovoltaic sub-cell 60, green wavelengths 65 for the middle photovoltaic sub-cell 70, and only a portion of the red light 75 for part of the bottom photovoltaic sub-cell 80. The FTIR portion of the standing evanescent wave that is coupled out into the receiving element or layer 40, may comprise only near infrared light (NIR).

The specific wavelength ranges of the standing wave and evanescent wave can be tailored to the selectivity (absorption and conversion preferences) of the photovoltaic cell by adjusting the materials used for the SOE 15, the intermediate layer 35, and the receiving element or layer 40 (which changes their relative refractive indices), and also by adjusting the distance between the SOE 15 and receiving element or layer 40 and/or the thickness of the intermediate layer 35.

As illustrated in FIG. 3, in some embodiments, one or more mirrors or reflective sides may be used as part of the concentrator assembly to further guide desired wavelengths of light through the SOE to the photovoltaic cell.

The present invention is not limited to the embodiments described above. Various changes and modifications can, of course, be made, without departing from the scope and spirit of the present invention. Additional advantages and modifications will readily occur to those skilled in the art. Accordingly, various modifications may be made without departing from the spirit or scope of the general inventive concept as defined by the appended claims and their equivalents.

We claim:

1. A heat-rejecting optic for reducing a thermal load on a photovoltaic cell, comprising:
a refractive optical element having a first refractive index
a receiver having a second refractive index; and
an intermediate layer having a third refractive index disposed between the refractive optical element and the receiver, the third refractive index being less than the first and second refractive indices, the first, second and third refractive indices selected to induce of light within the refractive optical element causing a selective wavelength of light to be ejected into the receiver.

2. The heat-rejecting optic of claim 1, wherein the refractive optical element and the receiver are separated by a distance that is on an order of one wavelength of the light being ejected into the receiver.

3. The heat-rejecting optic of claim 1, wherein the intermediate layer has a thickness that is on an order of one wavelength of the light being ejected into the receiver.

4. The heat-rejecting optic of claim 2, wherein the wavelength of the ejected light is a function of the distance separating the refractive optical element and the receiver.

5. The heat-rejecting optic of claim 3, wherein the wavelength of the ejected light is a function of the thickness of the intermediate layer.

6. The heat-rejecting optic of claim 3, wherein the wavelength of the ejected light is a function of a material composition of the intermediate layer.

7. A heat-rejecting optic for use in an array of photovoltaic cells, comprising:
an optical element having an edge and a first refractive index, and configured to provide substantially total internal reflection of incoming light; and
a receiving layer disposed along the edge of the optical element having a second refractive index, the receiving layer separated from the edge by an intermediate layer having a third refractive index, the third refractive index being less than the first and second refractive indices,
the intermediate layer and the receiving layer modifying the total internal reflection within the optical element to provide a frustrated total internal reflection resulting in coupling an evanescent wave created at the edge of the optical element out of the optical element through the intermediate layer and into the receiving layer.

8. The heat-rejecting optic of claim 7, wherein the coupled out evanescent wave comprises infrared radiation.

9. The heat-rejecting optic of claim 7, wherein the coupled out evanescent wave comprises wavelengths greater than 1800 nm.

10. The heat-rejecting optic of claim 7, wherein the intermediate layer is an air gap.

11. The heat-rejecting optic of claim 7, wherein the intermediate layer is magnesium fluoride (MgF₂).

12. The heat-rejecting optic of claim 7, wherein at least one of the optical element and the receiving layer is formed from glass.

13. The heat-rejecting optic of claim 7, wherein the receiving layer is formed from a silicone.

14. The heat-rejecting optic of claim 7, wherein the optical element is formed from glass and the receiving layer is formed from a silicone.

15. The heat-rejecting optic of claim 7, wherein the heat-rejecting optic is part of a high concentration photovoltaic system, HCPV.

16. The heat-rejecting optic of claim 15, wherein the high concentration photovoltaic system concentrates light 1000 times or more.

17. A lens concentrator system for rejecting heat on a photovoltaic cell comprising:
a photovoltaic cell;
a refractive optical element having a first refractive index disposed between a light source and the photovoltaic cell so that light enters the refractive optical element before reaching the photovoltaic cell;
a receiving element or layer having a second refractive index; and
an intermediate layer having a third refractive index, the intermediate layer disposed between the refractive optical element and the receiving element or layer, the third refractive index being less than the first and second refractive indices.

18. The system of claim 17, wherein the optical element is a primary optical element.

19. The system of claim 17, wherein the optical element is a secondary optical element.

20. The system of claim 19, wherein the secondary optical element is a prism.

21. The system of claim 19, wherein the secondary optical element is a light pipe.

22. The system of claim 19, further comprising an additional optical element, wherein the additional optical element is a primary optical element disposed between the secondary optical element and the light source.

23. The system of claim 22, wherein the primary optical element is a Fresnel lens.

24. The system of claim 17, wherein the photovoltaic cell is a multijunction photovoltaic cell.

25. The system of claim 17, wherein the multijunction photovoltaic cell is a III-V multi-junction photovoltaic cell.

26. A method of manufacturing a solar power modular assembly comprising:
selecting a secondary optical element having a selected refractive index;
coating the secondary optical element with magnesium fluoride (MgF₂), the selected refractive index being higher than the refractive index of magnesium fluoride (MgF₂); and
dipping the coated secondary optical element in a silicone, the silicone having a refractive index higher than the refractive index of magnesium fluoride (MgF₂).

27. The method of claim 26, wherein the magnesium fluoride (MgF₂) coating has a thickness selected based on a desired wavelength range of radiation to be rejected by the coated secondary optical element so that it does not reach the photovoltaic cell.

28. A method for reducing a thermal load on a photovoltaic cell comprising:
positioning an optical element above the photovoltaic cell, the optical element having a first refractive index;
positioning a receiving element or layer having a second refractive index adjacent and at a selected distance from the optical element and the selected distance providing an intermediate layer having a refractive index less than the first refractive index of the optical element and the second refractive index of the receiving element or layer so as to induce a standing evanescent wave formed in the optical element to couple out of the optical element and into the receiving element or layer.

29. The method of claim 28, wherein the wavelength of the standing evanescent wave induced to couple out of the optical element is selected by modifying at least one of the group consisting of:
(i) a distance between the optical element and the receiving element or layer,
(ii) a material composition of an intermediate layer between the optical element and the receiving element or layer, and
(iii) a thickness of the intermediate layer between the optical element and the receiving element or layer.
